(19) United States
(12) Patent Application Publication
(10) Pub. No.: US 2008/0182403 A1
(43) Pub. Date: Jul. 31, 2008

(54) UV CURING OF PECVD-DEPOSITED SACRIFICIAL POLYMER FILMS FOR AIR-GAP ILD

(76) Inventors: ATIF NOORI, Saratoga, CA (US); Francimar Schmitt, Santa Clara, CA (US); Annamalai Lakshmanan, Fremont, CA (US); Bok Hoen Kim, San Jose, CA (US); Reza Arghavani, Scotts Valley, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/017,879

(22) Filed: Jan. 22, 2008

Related U.S. Application Data
(60) Provisional application No. 60/886,872, filed on Jan. 26, 2007.

(51) Int. Cl. H01L 21/768

(52) U.S. Cl. 438/618; 257/E21.575

(57) ABSTRACT

Embodiments of the invention generally provide a method of forming an air gap between conductive elements of a semiconductor device, wherein the air gap has a dielectric constant of approximately 1. The air gap may generally be formed by depositing a sacrificial material between the respective conductive elements, depositing a porous layer over the conductive elements and the sacrificial material, and then stripping the sacrificial material out of the space between the respective conductive elements through the porous layer, which leaves an air gap between the respective conductive elements. The sacrificial material may be, for example, a polymerized alpha terpinene layer, the porous layer may be, for example, a porous carbon doped oxide layer, and the stripping process may utilize a UV based curing process, for example.

### CROSS-REFERENCE TO RELATED APPLICATIONS

This application claims benefit of U.S. provisional patent application Ser. No. 60/886,872, filed Jan. 26, 2007, which is herein incorporated by reference.

### BACKGROUND

1. Field

Embodiments of the invention as recited by the claims generally relate to a method for forming an air gap between conductive elements of a semiconductor device, wherein the air gap has a dielectric constant (k) of approximately 1.

2. Description of the Related Art

Reliably producing sub-quarter micron and smaller features on semiconductor substrates is a key technology for the next generation of very large scale integration (VLSI) and large-scale integration (ULSI) devices. However, as the fringes of circuit technology are advanced, the shrinking dimensions of the interconnect features places increasing demands on the processing techniques and the physical characteristics of the materials used to manufacture the devices. For example, in order to improve the density of semiconductor devices on integrated circuits, the size of features thereon has decreased to the sub-quarter micron range. Additionally, copper has essentially replaced aluminum as the primary conductor, primarily as a result of the lower resistivity provided by copper. Further, the shrinking dimensions have necessitated dielectric materials, i.e., the material positioned between the conductive features, having lower dielectric constants than previously utilized, i.e., low k, as defined herein, generally refers to dielectric constants of less than about 4.0, as the increased capacitive coupling between layers resulting from the closeness of the conductive elements can detrimentally affect the functioning of semiconductor devices.

A common method utilized to form the currently desired multilayer semiconductor devices is a damascene or dual damascene process. In a damascene method, for example, one or more low k dielectric materials are deposited and pattern etched to form the vertical and horizontal interconnects. Conductive materials, such as copper-containing materials and other conductive materials, such as barrier layer materials used to prevent diffusion of copper-containing materials into the surrounding low k dielectric material, are then inlaid into the etched pattern or features. These conductive materials are generally deposited in excess in order to insure that the features formed in the dielectric layer are adequately filled. However, the excess copper-containing materials and excess barrier layer material external to the etched pattern, such as on the field of the substrate, are generally removed via, for example, a chemical mechanical polishing process. Once the excess deposition is removed, the device generally has a substantially planar upper surface that includes the conductive and insulative elements exposed therefrom, and therefore, an insulating layer is generally deposited thereover to insulate the first layer of features from a second layer that may be deposited on top of the first layer.

However, one challenge associated with damascene processes is that as the size of the individual features therein continues to decrease in order to accommodate the increasing circuit density. As a result thereof, the dielectric constant of the material separating the respective conductive elements must also decrease in order to maintain electrical isolation of the respective conductive elements. Although current low k dielectric materials may provide a k value of between about 2.0 and about 3.5, for example, materials having lower dielectric constants will be required in order to support the continuing decrease in feature sizes and increases in circuit density.

Therefore, there exists a need for a spacer to be used between conductive elements of a semiconductor device, wherein the spacer provides a dielectric constant below about 2.

### SUMMARY OF THE INVENTION

Embodiments of the invention as recited by the claims generally provide a method of forming an air gap between conductive elements of a semiconductor device, wherein the air gap has a dielectric constant of approximately 1. The air gap may generally be formed by depositing a sacrificial layer between the respective conductive elements, depositing a porous layer over the conductive elements and the sacrificial layer, and then stripping the sacrificial layer out of the space between the respective conductive elements through the porous layer, which leaves an air gap between the respective conductive elements. The sacrificial layer may be, for example, a polymer such as alpha terpinene, the porous layer may be, for example, a porous oxide layer, and the stripping process may utilize an ultraviolet (UV) curing process, for example.

In certain embodiments a method for forming a low k spacer between conductive interconnects is provided. The method generally includes forming interconnect features into a sacrificial layer deposited on a substrate, wherein the sacrificial layer comprises polymerized alpha terpinene, and filling the interconnect features with a conductive material. The method further includes depositing a porous layer over the filled interconnect features and sacrificial layer, the porous layer having an ordered pore structure and stripping the sacrificial layer out of an area between the filled conductive interconnects through the porous layer to form an air gap between the conductive interconnects, wherein the stripping process comprises a UV based curing process. Finally, the method may include depositing a capping layer over the porous layer to seal the ordered pore structure.

In certain embodiments a method for forming a spacer between conductive members of a semiconductor device is provided. The method may generally include depositing a sacrificial layer on a substrate, forming features into the sacrificial layer, and filling the features with a conductive material. The method may further include depositing a porous layer over the filled interconnect features and sacrificial layer, the porous layer having an ordered pore structure, stripping the sacrificial layer out of an area between the filled conductive interconnects through the porous layer to form an air gap between the conductive interconnects, and depositing a capping layer over the porous layer to seal the ordered pore structure.

In certain embodiments a method for forming a spacer having a dielectric constant of about 1 between conductive features of a semiconductor device is provided. The method may include depositing a polymerized alpha terpinene layer onto a substrate using a chemical vapor deposition process, etching features into the polymerized alpha terpinene layer, and filling the features etched into the polymerized alpha terpinene layer with a conductive material using at least one of an electrochemical plating process, an electroless plating process, a physical vapor deposition process, and a chemical vapor deposition process. Additionally, the method may include using a chemical mechanical polishing process to planarize an upper surface of the semiconductor device, depositing a porous oxide layer over the filled features and the polymerized alpha terpinene layer, stripping the polymerized alpha terpinene layer from areas between conductive elements via a UV stripping process configured to remove the polymerized alpha terpinene layer through pores in the porous oxide layer, which operates to form an air gap between the conductive elements, and depositing a capping layer over the porous oxide layer to seal the pores.

In certain embodiments a method for forming a low k spacer between conductive interconnect features formed into a sacrificial layer on a semiconductor substrate is provided. The method may include depositing a porous layer over the interconnect features and the sacrificial layer, removing at least a portion the sacrificial layer out of an area between the conductive interconnect features through the porous layer to form an air gap between the conductive interconnect features, and depositing a capping layer over the porous layer to seal the porous layer. The resulting space between the interconnect features being filled with air, which generates a dielectric constant of about 1.

### BRIEF DESCRIPTION OF THE DRAWINGS

A more particular description of the invention, briefly summarized above, may be had by reference to certain embodiments, some of which are illustrated in the appended drawings. It is to be noted, however, that the appended drawings illustrate only certain embodiments, and therefore, are not to be considered limiting of its scope.

FIG. 1 illustrates an exemplary method for forming a low k air gap between conductive elements of a semiconductor device using a porous layer;

FIG. 2 illustrates an exemplary method for forming a low k air gap between conductive elements of a semiconductor device using a mask layer having apertures formed therein;

FIG. 3 illustrates an exemplary method for forming a low k air gap between conductive elements of a semiconductor device using a sacrificial layer; and

FIG. 4 illustrates an exemplary method for forming a low k air gap between conductive elements of a semiconductor device using a sacrificial layer and a carbon doped oxide layer.

To facilitate understanding, identical reference numerals have been used, wherever possible, to designate identical elements that are common to the figures. It is contemplated that elements and/or process steps of one embodiment may be beneficially incorporated in other embodiments without additional recitation.

### DETAILED DESCRIPTION OF THE PREFERRED EMBODIMENT

In certain embodiments a method for forming an air gap between conductive elements of a semiconductor device is generally provided. The air gap is generally formed by depositing a removable material between the conductive elements, depositing a porous layer over the removable material and the conductive elements, and then stripping the deposited material out of the space between the conductive elements through the porous layer to leave an air gap between the conductive elements. Although removable materials are discussed with reference to alpha terpinine, it should be understood that the exemplary methods described herein may be performed using other removable materials such as poly(methyl methacrylate) or parylenes.

Certain embodiments may be practiced on any plasma enhanced CVD chamber or system including systems such as the CENTURA ULTIMA HDP-CVD™ system, PRODUCER APF PECVD™ system, PRODUCER BLACK DIAMOND™ system, PRODUCER BLOK PECVD™ system, PRODUCER DARC PECVD™ system, PRODUCER HARP™ system, PRODUCER PECVD™ system, PRODUCER STRESS NITRIDE PECVD™ system, and PRODUCER TEOS FSG PECVD™ system, available from Applied Materials, Inc. of Santa Clara, Calif. An exemplary PRODUCER® system is further described in commonly assigned U.S. Pat. No. 5,855,681, issued Jan. 5, 1999, which is herein incorporated by reference.

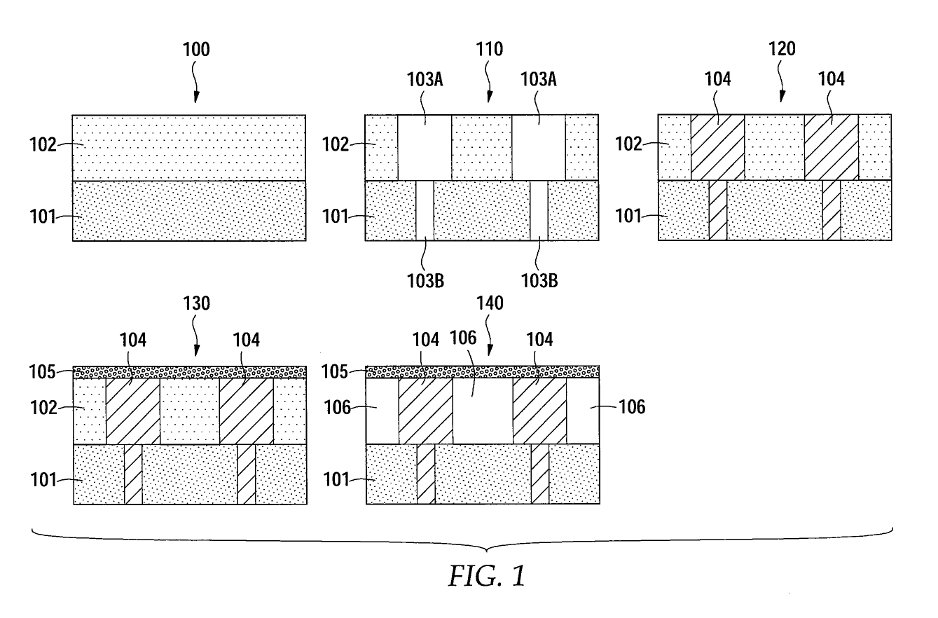

FIG. 1 illustrates an exemplary method for forming a gap or space between conductive elements of a semiconductor device, wherein the gap or space has a dielectric constant of less than about 2. The method begins at step 100, where a first layer, which may be a low dielectric constant material layer 101, such as a carbon doped oxide type layer, for example, is deposited on a semiconductor substrate (not shown). The low dielectric constant material layer 101 may be deposited, for example, using a chemical vapor deposition process or a plasma enhanced chemical vapor deposition process. A second layer 102, which may be a sacrificial layer, such as polymerized alpha terpinene, for example, may be deposited on top of the low dielectric constant material layer 101, and may be deposited via a plasma enhanced chemical vapor deposition process, for example. The sacrificial layer 102 may be formed via a deposition processing recipe that includes supplying alpha terpinene at a flow rate between about 100 mgm and about 5000 mgm, He at a flow rate between about 100 sccm and about 5000 sccm, O₂ at a flow rate between about 100 sccm and about 2000 sccm, a pressure of between about 2 torr and about 8 torr, a power between about 10 watts and about 1000 watts, a temperature of between about 100° C. and about 300° C., and a spacing between about 200 mils and about 1600 mils.

As such, the low dielectric constant material layer 101 may generally form a first layer, i.e., a layer that may be used for vias, plugs, and multilevel interconnect features, while the second layer 102 may be used for larger single layer features, such as trenches, for example. Once the first and second layers are formed on the substrate, various features may be formed into the respective layers, as illustrated in step 110, through known etching, lithography, or other methods calculated to form features into semiconductor device layers. For example, a trench 103A may be etched into second layer 102, and a via 103B may be etched into the first layer 101. Once the desired features are formed and/or etched into the respective layers, the features may be filled with a conductive material 104, which may be copper, for example, as illustrated in step 120. Although not illustrated, a barrier layer may be deposited into the respective features prior to the deposition of the conductive layer in order to prevent diffusion from the conductive layer into the adjoining layer. The conductive material 104 may be over deposited in order to adequately fill features 103A and 103B, and therefore, the upper surface of the conductive material 104 and the second layer 102 may be planarized to form a substantially planar surface, as illustrated in step 120.

Once the upper surface of the conductive material 104 and the second layer 102 is planarized, a porous layer 105 may be deposited thereon, as illustrated in step 130. The porous layer 105, which may generally be of sufficient thickness to provide structural rigidity and support to a subsequent layer deposited thereon, generally includes a relatively dense concentration of pores formed therein. The pores may be arranged in an organized interconnected manner, i.e., the pores in the respective layers may be generally in vertical alignment so that molecules may easily travel from one side of the porous layer to the other in a generally straight line via the organized interconnected pores. The organized interconnected pores generally represent aligned pores, i.e., similar to columns, so that molecules having a diameter less than the pore diameter may be communicated through the porous layer 105. Alternatively, the pores may be arranged in an unorganized manner, i.e., in a manner where the pores are not generally aligned vertically, and therefore, the pores do not generally form a straight line transmission path through the porous layer. In this arrangement, the pores will generally be offset from each other, and therefore, molecules traveling through the porous layer will travel a vertical distance through one pore and then travel horizontally to another pore before proceeding vertically thought the thickness of the layer. The porous layer 105 may be any number of porous layers, not limited to, for example, a porous oxide layer, a porous nitride layer, a porous BLOk layer, combinations of the aforementioned layers, or other porous layers known in the semiconductor art. The porous layer 105 may be, for example, between about 100 angstroms and about 1000 angstroms thick, and may have pores formed therein having a diameter of between about 10 angstroms and about 200 angstroms. More particularly, the porous layer 105 may be between about 200 angstroms and about 600 angstroms thick, and have pores formed therein having a diameter of between about 20 angstroms and about 60 angstroms.

The porous layer 105 may be a layer with highly controlled and reproducible ordered pore sizes and shapes formed using molecular self-assembly in a sol-gel condensation process. In this process, for example, a liquid solution is formed by means of the hydrolysis of a silicon alkoxide, such as tetraethylorthosilicate, within a solution comprised of a suitable water-soluble solvent, such as propylene glycol monopropyl ether, to which water and a suitable acid are added. The acid-catalyzed hyrolysis of silicon alkoxide produces a complex mixture of partially polymerized silanols suspended within the solution. A surfactant added to the solution provides the template structures for molecular self-assembly. A critical range of surfactant concentration is generally required for proper segregation of the surfactant into micelles during subsequent drying. A low concentration of tetramethylammonium salt may also be added to the chemical precursor solution to provide the chemical environment required during the final calcination step. The surfactant molecules, which are generally amphiphilic, may include a combination of hydrophobic and hydrophilic sections. During the early drying phase, the amphiphilic molecules self-assemble into structures oriented such that the short hydrophilic portions of the molecules are positioned on the outer surfaces of the structures, in contact with the water-soluble environment, while the extended hydrophobic portions cluster together comprising the inner body of the micelles. The solvated silanols coat the outer water-soluble portions of the self-assembled micelles, forming the embryonic porous film framework. During evaporation of the solvent, the structures generally form supramolecular assemblies.

During the layer deposition processing for porous layer 105 the liquid chemical precursor containing all of the required ingredients may be applied to a spinning substrate surface such that the chemical precursor coats the entire substrate surface. Substrate rotation velocity is then rapidly accelerated to a predetermined final spin speed which determines film thickness (film thickness is also influenced by certain additional factors, including solution viscosity). The solvent (together with most of the excess water content) evaporates during spinning, producing a “tacky” film. The film is then further dried on a hot plate, for example, at 140° C. for one minute. The final film structure is formed at a calcination step using an elevated temperature, which may be for example, between about 350° C. and about 400° C. During calcination, the surfactant templates are removed from the film by ablation, thus producing the desired film with interconnected ordered pores. The interconnected pore pathways aid extraction of the surfactant. The ordered pores are well characterized by a narrow distribution of pore size by virtue of the solvent-evaporation-induced self-assembled micelle formation as well as the uniform size of the surfactant molecules employed, which determines micelle size. Micelle size can be tuned by judicious selection of surfactant molecular dimensions, and total porosity can be adjusted by means of surfactant concentration employed within the chemical precursor solution. In certain embodiments, the porous layer 105 and the sacrificial layer 102 may be deposited in-situ. In other embodiments, the porous layer 105 and the sacrificial layer 102 may be deposited ex-situ.

The porous layer 105 may also be deposited through known semiconductor layer deposition techniques, such as, for example, chemical vapor deposition and plasma enhanced chemical vapor deposition processes. Once the porous layer 105 is deposited, the portions of the second layer 102 positioned between the respective features, i.e., the polymerized alpha terpinene layer separating the respective conductive features in the second level, may be removed by a stripping process, as illustrated in step 140. The stripping process, which may be a UV based curing process if second layer 102 is a sacrificial layer, such as polymerized alpha terpinene, for example, generally operates to dissociate the molecules forming the sacrificial layer between the respective conductive elements to flow out of the region between the conductive elements through the porous layer 105. As a result thereof, the region between the conductive elements is emptied of the sacrificial material residing therein, and therefore, an air gap 106 is formed between the respective conductive elements. Inasmuch as air is generally known to have a dielectric constant of 1, the removal of the sacrificial layer from the region between the respective conductive elements leaving the air gap 106 therebetween operates to generate a dielectric constant of approximately 1 between the respective conductive members. An exemplary process for stripping the organic layer through the pores employs a UV based curing process. This UV cure may be performed in a fraction of the time as thermal only curing. The process may be carried out using a UV system manufactured by Applied Materials of Santa Clara, Calif., for example a NanoCure system. Other UV systems, such as the system described in U.S. patent application Ser. No. 11/124,908, filed on May 9, 2005, entitled TANDEM UV CHAMBER FOR CURING DIELECTRIC MATERIALS, published as U.S. 2006/0251827, which is herein incorporated by reference to the extent not inconsistent with the current specification, may also be used. This process may be carried out using a static or dual-sweeping source. The chamber pressure may be between about 2 torr and about 12 torr, the chamber temperature may be between about 50° C. and about 600° C. The wavelength of the UV source may be between about 200 nm and about 300 nm. Helium gas may be supplied at a flow rate of between about 100 sccm and 20,000 sccm. In certain embodiments, additional gases such as argon, nitrogen, and oxygen or any combination thereof may be used. The UV power may be between about 25% and about 100% and the processing time period may be between about 0 minutes and about 200 minutes. Once the stripping process is complete, a capping or sealing layer (not shown), which may also be a low k-type material, may be deposited over the porous layer 105 in order to seal the pores formed therein and prevent backflow of material into the air gap region.

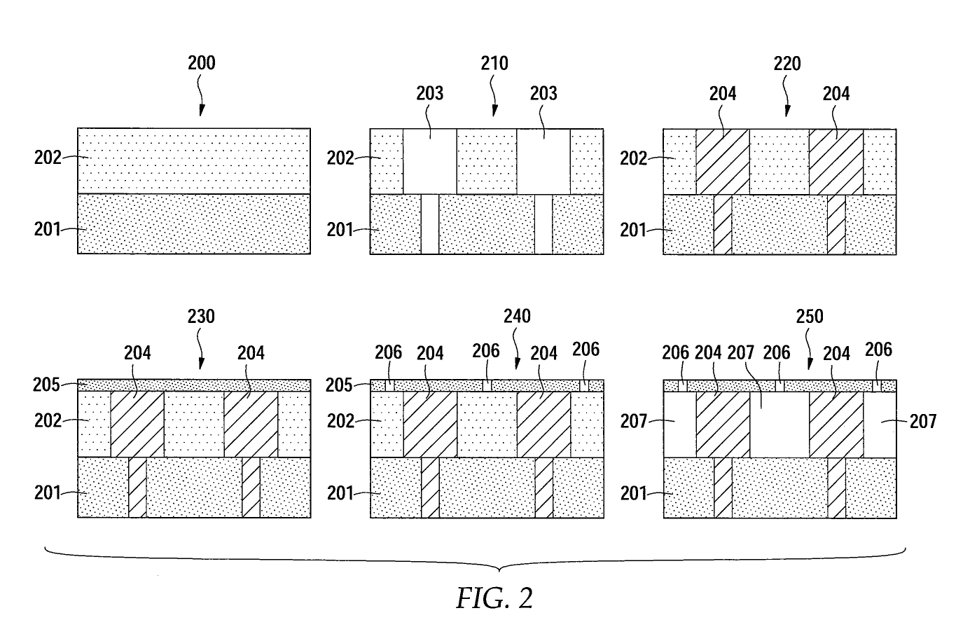

In certain embodiments, an air spacer may be formed without using a stripping process, as the sacrificial layer is removed from a region between conductive elements through an aperture formed into an overlying layer. In this embodiment, which is illustrated in FIG. 2, a low or low dielectric constant material layer 201, such as a carbon containing silicon oxide layer, for example, is deposited on a semiconductor substrate, and a sacrificial layer, which may be a polymerized alpha terpinene layer 202 is deposited over the low dielectric constant material layer 201, as illustrated in step 200. In similar fashion to the embodiment illustrated in FIG. 1, layers 201 and 202 may be formed through a plurality of known deposition processes, such as, for example, chemical vapor deposition. Once the layers 201 and 202 are formed, various features 203, i.e., lines, plugs, vias, trenches, etc., may be formed into layers 201 and 202 as desired to support the devices being manufactured, as illustrated in step 210. The process of forming features 203 into layers 201 and 202 may be conducted through a number of processes known in the semiconductor art, such as, for example, an etching process. Once features 203 are formed, a conductive material 204, such as copper, for example, may be deposited into the respective features 203, as illustrated in step 220. More particularly, for example, a copper deposition process, such as physical vapor deposition, chemical vapor deposition, and/or electroplating may be used to form a copper fill layer over the entire surface of the substrate, including the features and the upper surface of the sacrificial layer 202 comprising polymerized alpha terpinene. Further, if desired, a barrier layer may be deposited prior to the conductive material 204, wherein the barrier layer is configured to prevent diffusion of the conductive material 204 into the surrounding layers. The conductive material 204 is generally formed using an over deposition process, i.e., copper is deposited in an amount sufficient to fill each of the features 203, which generally means that the copper is over deposited onto the upper surface of the sacrificial layer 202. As such, various planarization techniques, such as chemical mechanical polishing and etch back techniques, for example, may be used to planarize the upper surface of the sacrificial layer 202, as well as the upper conductive surface of the features 203 having the conductive material 204 deposited therein. Regardless of the planarization technique employed, the end result is that the upper surface is planarized, as shown in step 220. In certain embodiments, the conductive material 204 may be cured either before or after metal planarization.

Once the upper surface is planarized, a mask layer 205 may be deposited over the sacrificial layer 202 and the conductive features 204 formed therein, as illustrated in step 230. The mask layer 205 may be formed of a barrier layer material and/or other low k material, which are generally referred to as silicon carbide layers. The low k layer, along with any of the aforementioned low k layers may be formed via a deposition processing recipe that includes trimethylsilane (TMS) between about 300 sccm and about 2,500 sccm, He up to about 5,000 sccm, NH₃ up to about 1,000 sccm, a pressure of between about 1 torr and about 14 torr, a power between about 50 watts and about 1,500 watts, and a temperature of between about 300° C. and about 400° C. The mask layer 205 may generally have a thickness of between about 100 angstroms and about 1,000 angstroms, however, masks of greater or lesser thicknesses may also be implemented. Once mask layer 205 is formed, a plurality of mask holes or apertures 206 may be formed therein, as illustrated in step 240. The mask holes 206 may generally be positioned above the area separating the respective conductive members 204, i.e., holes 206 are generally positioned above the sacrificial layer 202 and offset from the conductive members 204. Once mask holes 206 are formed, the method continues to step 250, wherein the sacrificial material separating the respective conductive members 204 is removed from the area between the respective conductive members 204. The apertures 206 may be circular holes or chimneys strategically placed over the sacrificial layer, or alternatively, the apertures 206 may be elongated holes or channels that track over a portion of the sacrificial layer to be stripped from thereunder. The removal process generally includes stripping out the sacrificial material separating the respective conductive members 204 with a stripping process in order to yield an air gap or space 207 between the respective conductive members 204. Assuming that the sacrificial material separating conductive members 204 is a polymerized alpha terpinene layer, a UV based curing process may be used to remove the polymerized alpha terpinene from the areas between the conductive members 204. As such, the stripping process generally includes the application of UV light to the polymerized alpha terpinene layer via mask holes 206, such that the polymerized alpha terpinene may be removed from the area between conductive members 204 by traveling out of the area of via mask hole 206. The result of the stripping process once the polymerized alpha terpinene is removed from the area between the conductive members 204 is that an air gap 207 is formed between the respective conductive members 204. Although a residue of the polymerized alpha terpinene may remain in the air gap region, the space between conductive members 204 is generally an air space, and therefore, provides the dielectric constant of approximately 1. Further, in order to seal the holes 206, a capping layer (not shown) may be deposited over the top of the mask layer 205. The capping layer may be a porous oxide layer, a porous nitride layer, a porous silicon carbide layer, or other layer suitable for capping in a semiconductor device.

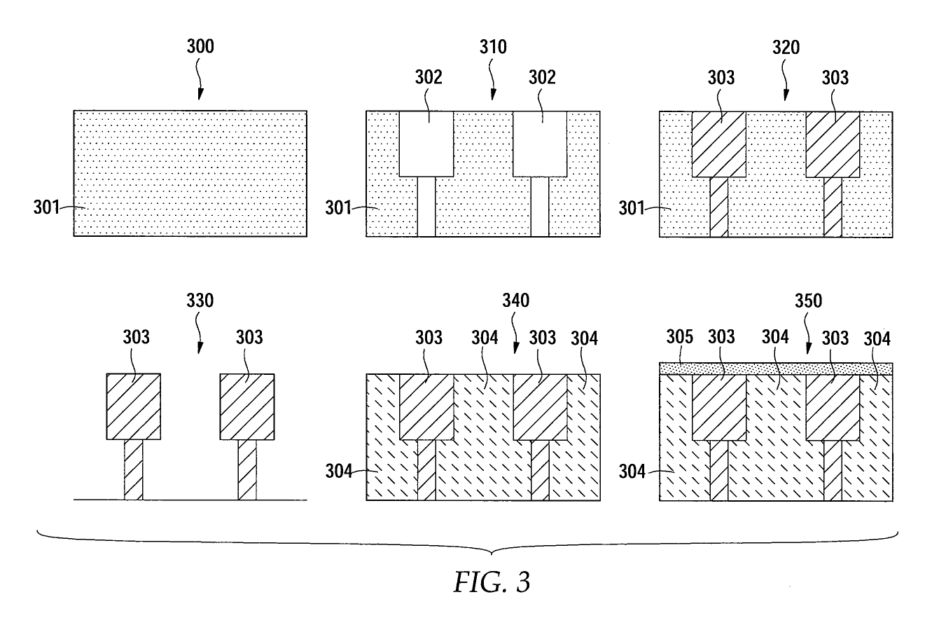

In another embodiment of the invention, which is illustrated in FIG. 3, a damascene process may be used to generate a low k spacer between conductive members of a semiconductor device. The damascene process generally includes depositing a polymerized alpha terpinene layer 301 onto a substrate (not shown), as illustrated in step 300. The polymerized alpha terpinene layer 301 is generally of sufficient thickness to have semiconductor device features formed therein, and may be deposited through known semiconductor deposition techniques, such as, for example, plasma enhanced chemical vapor deposition. Once the polymerized alpha terpinene layer is formed, the method continues to step 310, where various interconnect features 302 are formed into the polymerized alpha terpinene layer 301. The various interconnect features 302, which may be trenches and/or vias, for example, may be formed into the polymerized alpha terpinene layer 301 via an etch process. Once features 302 are formed into the polymerized alpha terpinene layer 301, the features may be filled with a conductive material 303, which may be copper, for example. The conductive material 303 may be deposited onto the polymerized alpha terpinene layer 301 and into the features 302 via known semiconductor deposition techniques, such as, for example, physical vapor deposition, chemical vapor deposition, electroless deposition, and/or electrochemical deposition processes, as illustrated in step 320. The process of depositing the conductive material 303 into features 302 generally includes over depositing the conductive material 303 and then removing the over deposition via a planarization or polishing process, as is known in the semiconductor art. Regardless of the fill and/or planarization processes employed, the end result is to fill features 302 with conductive material 303 and to generate a substantially planar upper surface above features 302 that is generally in the same plane as the upper surface of the remaining polymerized alpha terpinene layer 301.

Once features 302 are filled with the conductive material 303 and planarized, the polymerized alpha terpinene layer positioned between the respective conductive features 302 may be completely removed therefrom. The removal process may generally include a UV based curing process configured to completely remove the polymerized alpha terpinene layer 301, as illustrated in step 330. Once the interstitially positioned polymerized alpha terpinene is removed, the space previously occupied by the polymerized alpha terpinene may be filled with an extremely low k material 304. Although various extremely low k materials are contemplated within the scope of the present invention, generally, the dielectric constant of the material deposited between conductive elements 303 is in the range of about 1.7 to about 2.2, and preferably, about 2. In similar fashion to the metal deposition process illustrated in step 320, the deposition of the extremely low k material 304 also generally includes over deposition thereof in order to completely fill the space previously occupied by the polymerized alpha terpinene. As a result thereof, step 340 also generally includes a planarization step, such as a chemical mechanical polishing process, configured to planarize the upper surface of the conductive material 303 and the extremely low k material 304 deposited between the material 303 elements. Once the planarization process is complete, the method continues to step 350, wherein a barrier layer 305 is deposited over the top of the conductive features 303 and the extremely low k layer 301. Barrier layer 305 generally operates to electrically isolate the conductive elements present in the layer formed beneath it from subsequent conductive elements deposited in a layer formed above barrier layer 305.

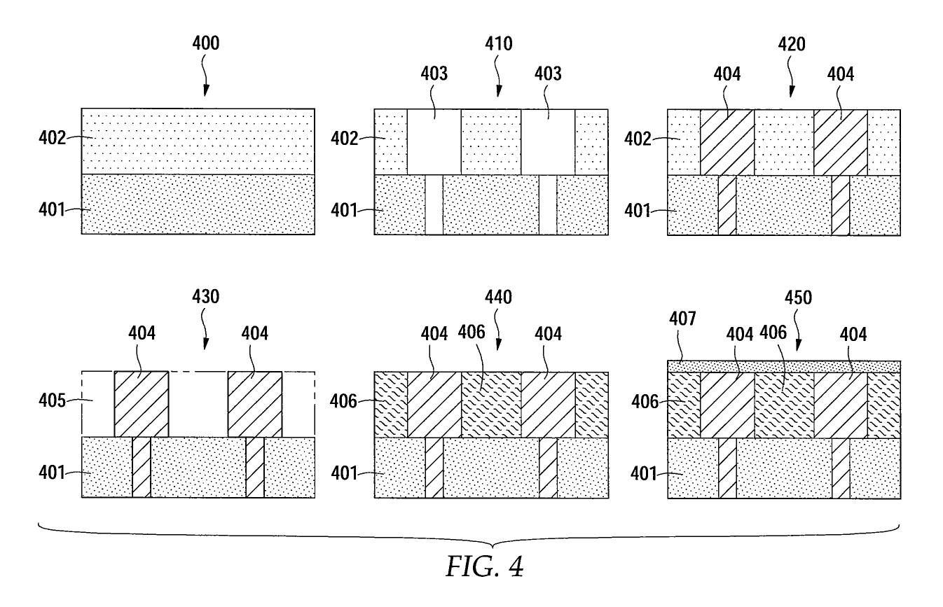

In certain embodiments, a damascene method is provided for generating a low k spacer between conductive elements of a semiconductor device. As illustrated in FIG. 4, the method generally begins at step 400 with the deposition of the low k material layer 401 onto a substrate (not shown); it continues with the deposition of a polymerized alpha terpinene layer 402 on top of layer 401. The low k material layer 401 may generally be a carbon containing silicon oxide type layer. An exemplary carbon containing silicon oxide material is described in U.S. patent application Ser. No. 11/076,181, filed Mar. 9, 2005, and entitled METHOD FOR FORMING ULTRA LOW K FILMS USING ELECTRON BEAM, published as U.S. 2005/0153073, which is herein incorporated by reference to the extent not inconsistent with the current specification. Once layers 401 and 402 are formed, the method continues to step 410, where various device features 403 may be formed into layers 401 and 402. The device features 403, which may be trenches, vias, or other features known to support semiconductor device formation, may be formed through an etch process, for example. Once the respective features 403 are formed, the method continues to step 420, where features 403 are filled with a conductive material 404. The conductive material, which may be copper, for example, may be filled into features 403 using known semiconductor layer formation techniques, such as, for example, physical vapor deposition, chemical vapor deposition, and/or electrochemical plating techniques. Regardless of the deposition techniques employed, the metal layer is generally over deposited into features 403, and therefore, is generally planarized subsequent to deposition.

Once the features are formed and are filled with a conductive material, the method generally continues to step 430, where in the polymerized alpha terpinene layer 402 may be removed from the areas between the conductive features 404. The removal of the polymerized alpha terpinene layer may generally be accomplished via a UV curing process, or other process generally known to be effective in removing polymerized alpha terpinene type layers. Once the polymerized alpha terpinene is removed, which essentially yields an airspace between the respective conductive material 404, the method continues to step 440, where the airspace is formed by the removal of the polymerized alpha terpinene material and filled with an extremely low k material 406. In similar fashion to the metal deposition process, the deposition of the extremely low k material is generally accomplished in over deposition process, and therefore, the over deposited material is generally removed from the surface of the device through, for example, a chemical mechanical polishing process. Therefore, when step 440 is completed, the device will generally include conductive members 404 having a material positioned therebetween that has an extremely low dielectric constant. Furthermore, the upper surface of the device, i.e., the upper surface of conductive members 404 into the upper surface of the material having the extremely low dielectric constant, is substantially planar is a result of the chemical mechanical planarization process. Thereafter, the method continues to step 450, wherein a barrier layer 407 is deposited over the conductive features 404 and the material having an extremely low dielectric constant 406.

While the foregoing is directed to embodiments of the present invention, other and further embodiments of the invention may be devised without departing from the basic scope thereof, and the scope thereof is determined by the claims that follow.

1. A method for forming a low k spacer between conductive interconnects, comprising:
forming interconnect features into a sacrificial layer deposited on a substrate, wherein the sacrificial layer is a polymerized alpha terpinene layer;
filling the interconnect features with a conductive material;
depositing a porous layer over the filled interconnect features and sacrificial layer, the porous layer having an ordered pore structure; and
removing at least a portion of the sacrificial layer out of an area between the filled conductive interconnects through the porous layer to form an air gap between the conductive interconnects.

2. The method of claim 1, wherein the removing step comprises a UV based curing process.

3. The method of claim 1, further comprising depositing a capping layer over the porous layer to seal the ordered pore structure.

4. The method of claim 1, wherein the air gap provides a dielectric constant of about 1.

5. The method of claim 1, wherein the filling process comprises at least one of a physical vapor deposition process, a chemical vapor deposition process, an electrochemical plating process, and an electroless plating process.

6. The method of claim 1, wherein the porous layer comprises a porous carbon containing oxide layer.

7. The method of claim 1, further comprising planarizing an upper surface of the substrate between the filling step and the step of depositing a porous layer, wherein the planarizing comprises using chemical mechanical polishing.

8. The method of claim 1, wherein depositing the porous layer comprises:
depositing a liquid solution over the substrate, the liquid solution reacting to form partially polymerized silanols suspended in the solution; and
curing the solution on the substrate to form the porous layer.

9. The method of claim 1, wherein the depositing a porous layer and depositing a capping layer are performed in-situ.

10. A method for forming a spacer between conductive members of a semiconductor device, comprising:
depositing a sacrificial layer on a substrate;
forming features into the sacrificial layer;
filling the features with a conductive material;
depositing a porous layer over the filled interconnect features and sacrificial layer, the porous layer having an ordered pore structure;
stripping the sacrificial layer out of an area between the filled conductive interconnects through the porous layer to form an air gap between the conductive interconnects, wherein the stripping process comprises a UV based curing process; and
depositing a capping layer over the porous layer to seal the ordered pore structure.

11. The method of claim 10, wherein the sacrificial layer is a polymerized alpha terpinene layer.

12. The method of claim 11, wherein the depositing a sacrificial layer on the substrate comprises:
flowing alpha terpinene at a rate between 100 mgm and 5000 mgm;
flowing helium at a rate between 100 sccm and 5000 sccm; and
flowing oxygen at a rate between 100 sccm and 2000 sccm.

13. The method of claim 10, wherein the sacrificial layer is a porogen.

14. The method of claim 10, wherein the porous layer is a porous carbon doped oxide layer.

15. The method of claim 10, wherein the stripping process comprises stripping the sacrificial layer out of an area between the features through an aperture formed in the porous layer.

16. The method of claim 10, further comprising depositing a barrier layer on the features formed in the sacrificial layer prior to filling the features with a conductive material.

17. The method of claim 10, wherein the air gap provides a dielectric constant of about 1.

18. The method of claim 10, wherein the porous layer is selected from the group comprising a porous oxide layer, a porous nitride layer, and a porous silicon carbide layer.

19. The method of claim 10, further comprising planarizing an upper surface of the semiconductor device between the filling step and the step of depositing a porous layer.

20. A method for forming a spacer having a dielectric constant of about 1 between conductive features of a semiconductor device, comprising:
depositing a polymerized alpha terpinene layer onto a substrate using a plasma enhanced chemical vapor deposition process;
etching features into the polymerized alpha terpinene layer;
filling the features etched into the polymerized alpha terpinene layer with a conductive material using at least one of an electrochemical plating process, an electroless plating process, a physical vapor deposition process, and a chemical vapor deposition process;
using a chemical mechanical polishing process to planarize an upper surface of the semiconductor device;
depositing a porous oxide layer over the filled features and the polymerized alpha terpinene layer;
stripping the polymerized alpha terpinene layer from areas between conductive elements via a UV based curing process configured to remove the polymerized alpha terpinene layer through pores in the porous oxide layer, which operates to form an air gap between the conductive elements; and
depositing a capping layer over the porous oxide layer to seal the pores.
